(19) United States
(12) Patent Application Publication
(10) Pub. No.: US 2018/0374706 A1
(43) Pub. Date: Dec. 27, 2018

(54) CORROSION RESISTANT COATING FOR SEMICONDUCTOR PROCESS EQUIPMENT

(71) Applicant: APPLIED MATERIALS, INC., Santa Clara, CA (US)

(72) Inventors: YOGITA PAREEK, Jaipur (IN); GEETIKA BAJAJ, New Delhi (IN); PRERNA GORADIA, Mumbai (IN); ANKUR KADAM, Thane (IN); BIPIN THAKUR, Mumbai (IN)

(21) Appl. No.: 16/062,177

(22) PCT Filed: Dec. 22, 2016
(86) PCT No.: PCT/US2016/068202

§ 371 Date: Jun. 14, 2018

(30) Foreign Application Priority Data
Dec. 22, 2015 (IN) 4236/DEL/2015

(51) Int. Cl. H01L 21/288; H01L 21/67; H01L 21/687; C25D 3/44; C25D 7/12

(52) U.S. Cl. CPC H01L 21/288; H01L 21/6719; C25D 7/12; C25D 3/44; H01L 21/68757

(57) ABSTRACT

A corrosion resistant coating for semiconductor process equipment and methods of making corrosion resistant coatings for semiconductor process equipment are provided herein. In some embodiments, a method of treating a semiconductor processing chamber component, includes: anodizing a semiconductor processing chamber component comprising an aluminum containing body in an anodizing solution comprising a neutral electrolyte and a resistive material to form a corrosion resistant coating atop the aluminum containing body. In some embodiments, a method of treating a semiconductor processing chamber component, includes: anodizing a semiconductor processing chamber component comprising an aluminum containing body in a neutral electrolyte solution to form an aluminum oxide layer on a surface of the aluminum containing body; and dipping the anodized semiconductor processing chamber component in a resistive material solution to form a resistive material layer atop the aluminum oxide layer.

### FIELD

Embodiments of the present disclosure generally relate to a corrosion resistant coating for semiconductor process equipment and methods of making corrosion resistant coatings for semiconductor process equipment.

### BACKGROUND

During processing of a substrate (e.g. a semiconductor wafer) in a substrate process chamber (e.g. a semiconductor processing chamber), as in the manufacture of integrated circuits and displays, the substrate is typically exposed to energized gases that are capable of, for example, etching or depositing material on the substrate. The energized gases can also be provided to clean surfaces of the substrate process chamber. However, the energized gases can often comprise corrosive halogen-containing gases and other energized species that can erode components of the substrate process chamber, such as the chamber enclosure wall, showerhead, a substrate support pedestal, a liner, or the like. For example, substrate process chamber components (e.g. chamber components) made of aluminum can chemically react with energized halogen-containing gases to form aluminum chloride (AlCl₃) or aluminum fluoride (AlF₃), which corrode the chamber components. The corroded portions of the chamber components can flake off and contaminate the substrate, which reduces the substrate yield. Thus, the corroded chamber components are frequently replaced or removed from the substrate process chamber and cleaned, resulting in undesirable substrate process chamber downtime.

Currently, chamber components are treated, for example by a hard anodizing process or a plasma electrolytic oxidation process (PEO), resulting in the formation of a porous aluminum oxide layer on the chamber component. Anodizing is typically an electrolytic oxidation process that produces an integral coating of relatively porous aluminum oxide on the aluminum surface. However, the typical anodization processes result in a porous layer, which allows the halide component to eventually reach and react with the aluminum surface of the chamber component.

Accordingly, the inventors have developed an improved corrosion resistant coating for semiconductor process equipment and methods of making corrosion resistant coatings for semiconductor process equipment.

### SUMMARY

A corrosion resistant coating for semiconductor process equipment and methods of making corrosion resistant coatings for semiconductor process equipment are provided herein. In some embodiments, a method of treating a semiconductor processing chamber component, includes: anodizing a semiconductor processing chamber component comprising an aluminum containing body in an anodizing solution comprising a neutral electrolyte and a resistive material to form a corrosion resistant coating atop the aluminum containing body.

In some embodiments, a method of treating a semiconductor processing chamber component, includes: anodizing a semiconductor processing chamber component comprising an aluminum containing body in a neutral electrolyte solution to form an aluminum oxide layer on a surface of the aluminum containing body; and dipping the anodized semiconductor processing chamber component in a resistive material solution to form a resistive material layer atop the aluminum oxide layer.

In some embodiments, a semiconductor processing chamber component, includes: an aluminum containing body; and a corrosion resistant coating covering a surface of the substrate processing chamber component wherein the corrosion resistant coating comprises aluminum oxide and a resistive material.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. The appended drawings illustrate only typical embodiments of the disclosure and are therefore not to be considered limiting of the scope, for the disclosure may admit to other equally effective embodiments.

FIG. 1 depicts a flow chart for a method of treating a semiconductor processing chamber component in accordance with some embodiments of the present disclosure.

FIG. 2 depicts a flow chart for a method of treating a semiconductor processing chamber component in accordance with some embodiments of the present disclosure.

FIGS. 3A-3D depict the stages of treating a semiconductor processing chamber component in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Improved corrosion resistant coatings for semiconductor process equipment and methods of making corrosion resistant coatings for semiconductor process equipment are disclosed herein. In some embodiments, the corrosion resistant coating formed herein may be used with any suitable semiconductor process chamber component (e.g. chamber component) that is exposed to corrosive chemistries within a semiconductor process chamber (e.g. process chamber), such as but not limited to chlorine or fluorine containing process chemistries. Embodiments of the current disclosure advantageously form a corrosion resistant coating atop chamber components which prevents corrosive chemistries within a process chamber from reacting with and corroding chamber components, such as a showerhead, a substrate support pedestal, a liner, or the like. Other benefits may also be realized via the methods and structures disclosed herein.

The inventors have observed that chamber components used in typical chemical vapor deposition processes (CVD) or atomic layer deposition (ALD) processes are frequently exposed to corrosive chemistries that can corrode chamber components. For example, chemical precursors used in CVD or ALD processes for depositing material atop a substrate, such as a semiconductor wafer, may contain corrosive elements that can corrode chamber components. Alternatively, chamber components may be exposed to corrosive chemistries during in-situ chamber cleaning processes, typically using a halogen containing gas such as fluorine or a chlorine containing gases.

The inventors have observed that chamber components, including but not limited to a showerhead or a substrate support pedestal or components of a substrate support pedestal, may be composed of a material, such as aluminum or an aluminum alloy, which is especially susceptible to corrosion from halogen containing gases (e.g. fluorine containing gases or chlorine containing gases). The inventors have further observed that chamber components are typically treated using a process such as hard anodization or plasma electrolytic oxidation (PEO) which results in the formation of a porous aluminum oxide layer on the chamber component. However, the porous aluminum oxide layer allows the halide component of the relevant chemistry to eventually reach and react with the aluminum surface of the chamber component to erode the chamber component.

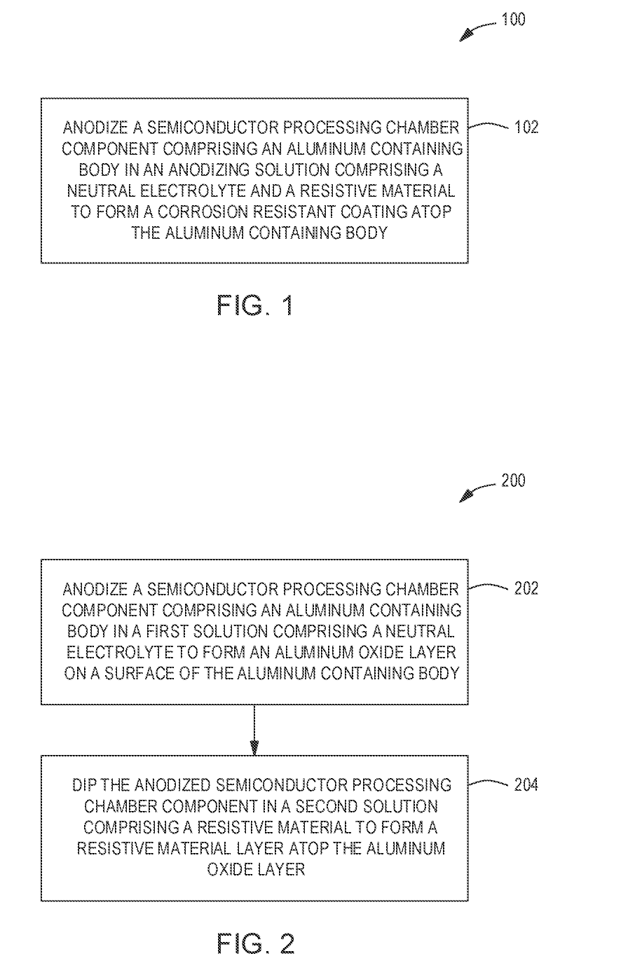

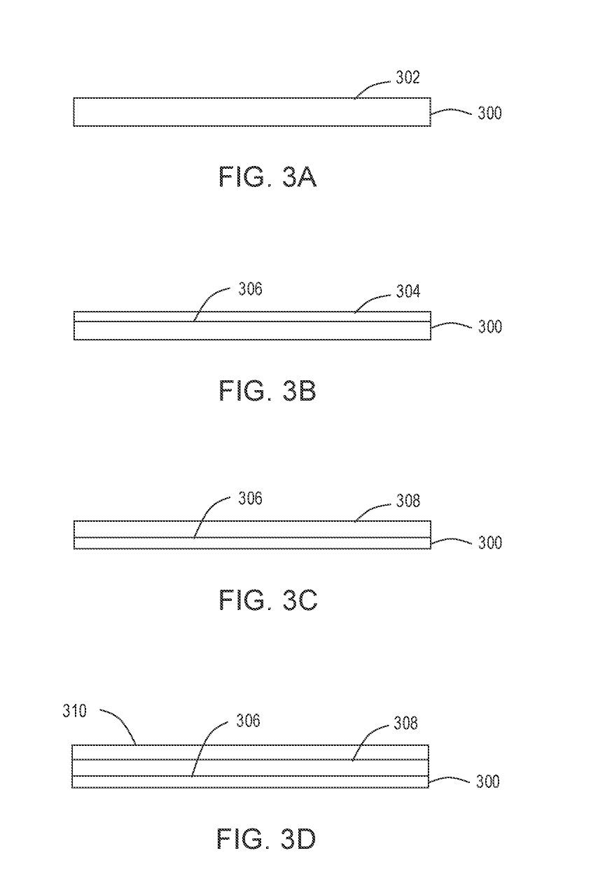

FIG. 1 depicts a flow chart of a method 100 for treating a chamber component in accordance with some embodiments of the present disclosure. The method 100 begins at 102 where a chamber component 300 having an exposed aluminum surface 302, as depicted in FIG. 3A is dipped in an anodizing solution to anodize the chamber component 300. The anodizing solution comprises a neutral electrolyte and a resistive material. In some embodiments, the anodizing solution consists of, or consists essentially, of a neutral electrolyte and a resistive material. While typical anodization processes utilize an acidic electrolyte such as sulfuric acid (H₂SO₄) or an oxalic acid having a pH of less than about 2, the inventors have observed that anodizing in a solution comprising a neutral electrolyte and a resistive material advantageously forms a denser, less-porous corrosion resistant coating. For example, anodizing in a solution comprising a neutral electrolyte and a resistive material advantageously forms a corrosion resistant coating having a density of about 2.3 g/cm³ and porosity of less than about 5%. The chamber component 300 to be anodized is immersed in the anodizing solution and functions as an anode in the anodizing solution. In some embodiments, the chamber component 300 is coupled to an electrical power source and a current is applied to the chamber component 300. In some embodiments, the chamber component 300 is coupled to the positive terminal of the electrical power source. A cathode is immersed in anodizing solution and is connected to the electrical power source. In some embodiments, the cathode is coupled to the negative terminal of the electrical power source. In some embodiments, the electrical power source provides about 20 mV to about 300 volts of power. In some embodiments, the chamber component 300 can be anodized for any suitable length of time to form a corrosion resistant coating having a predetermined thickness. For example, in some embodiments, the chamber component 300 can be anodized for about 60 to about 900 seconds. In some embodiments, the exposed aluminum surface 302 of the chamber component 300 that is exposed to corrosive chemistries in the process chamber is immersed in the anodizing solution. Accordingly, as depicted in FIG. 3B, the exposed aluminum surface 302 is converted into a corrosion resistant coating 304 comprising aluminum oxide and a resistive material atop a remaining aluminum surface 306. In some embodiments, the exposed aluminum surface 302 of the chamber component 300 is converted into a corrosion resistant coating consisting of, or consisting essentially of, aluminum oxide and a resistive material. For example, in some embodiments, the corrosion resistant coating is a composite coating of aluminum and zirconium, or aluminum and yttrium, or aluminum and polytetrafluoroethylene (e.g., Teflon). In some embodiments, the corrosion resistant coating 304 is integrally formed on the chamber component 300.

In some embodiments, the neutral electrolyte has a pH from about 6 to about 8, such as ammonium borate (H₁₂BN₃O₃), ammonium aditate, ammonium titrate, or ammonium phosphate (H₁₂N₃O₄P), or the like. The neutral electrolyte helps to form a dense and non-porous oxide layer on the chamber component 300.

In some embodiments, the resistive material is yttrium, zirconium, cerium, polytetrafluoroethylene (e.g., Teflon), or the like. Anodization of the chamber component 300 in the anodizing solution having a resistive material, such as Teflon, with a neutral electrolyte, such as ammonium phosphate, will form a dense and plasma resistive material on the chamber component 300. Chamber components having with the corrosion resistant coating 304 will advantageously not react aggressively with corrosive chemistries being used in typical semiconductor process chamber, such as deposition or etch processes, and improve the productivity of the semiconductor process chamber. In some embodiments, the molar ratio of resistive material to neutral electrolyte in the anodizing solution is about 0.5:1 to about 1:1. The anodization process parameters discussed above, such as the anodizing solution, the electrical power, and the duration of the anodizing process may be selected to form a corrosion resistant coating 304 having predetermined properties, such as for example a predetermined thickness or corrosion resistance. In some embodiments, the corrosion resistant coating 304 has a thickness of about 20 nm to about 500 nm.

In some embodiments, the chamber component 300 may be annealed in an oxygen containing atmosphere after anodizing the chamber component 300. In some embodiments, a suitable oxygen containing gas can be, for example, a gas that provides oxygen and other essentially non-reactive elements, such as ozone (O₃), nitric oxide (NO), nitrous oxide (N₂O), oxygen (O₂), water vapor (H₂O), or combinations thereof. In some embodiments, the chamber component 300 may be annealed at a temperature of about 200 to about 400 degrees Celsius. In some embodiments, the chamber component 300 may be annealed for about 120 to about 1800 seconds. Annealing the chamber component 300 helps to provide a unitary structure between the metal of the underlying chamber component 300 and the corrosion resistant coating 304. Specifically, the annealing process allows the corrosion resistant coating 304 and the aluminum surface 306 to at least partially defuse into each other, resulting in a more integral and unitary corrosion resistant coating 304.

FIG. 2 depicts a method 200 of treating a chamber component 300 in accordance with some embodiments of the present disclosure. The method begins at 202 by anodizing a chamber component 300 having an exposed aluminum surface 302, as depicted in FIG. 3A in a neutral electrolyte solution. In some embodiments, the neutral electrolyte solution consists of, or consists essentially of, the neutral electrolyte. In some embodiments, the neutral electrolyte in the neutral electrolyte solution has a pH from about 6 to about 8. In some embodiments, the neutral electrolyte is ammonium borate (H₁₂BN₃O₃), ammonium aditate, ammonium titrate, or ammonium phosphate (H₁₂N₃O₄P), or the like. The neutral electrolyte helps to form a dense and non-porous oxide layer on the chamber component 300.

The chamber component 300 to be anodized is immersed as the anode in the neutral electrolyte solution and a current is applied. The chamber component 300 to be anodized is immersed in the neutral electrolyte solution and functions as an anode in the neutral electrolyte solution. In some embodiments, the chamber component 300 is coupled to an electrical power source and a current is applied to the chamber component 300. In some embodiments, the chamber component 300 is coupled to the positive terminal of the electrical power source. A cathode is immersed in the neutral electrolyte solution and is connected to the electrical power source. In some embodiments, the cathode is coupled to the negative terminal of the electrical power source. In some embodiments, the electrical power source provides about 2 to about 300 volts of power. In some embodiments, the chamber component 300 can be anodized for any suitable length of time to form a first corrosion resistant coating 308 having a predetermined thickness. For example, in some embodiments, the chamber component 300 can be anodized for about 60 to about 900 seconds. In some embodiments, the exposed aluminum surface 302 of the chamber component 300 that is exposed to corrosive chemistries in the process chamber is immersed in the anodizing solution. As depicted in FIG. 3C, the exposed aluminum surface 302 of the semiconductor processing chamber component is converted into a first corrosion resistant coating 308 comprising aluminum oxide, or in some embodiments consisting of or consisting essentially of aluminum oxide, atop the aluminum surface 306. In some embodiments, the first corrosion resistant coating 308 is integrally formed on the chamber component 300. Anodization process parameters, such as the composition of the anodizing solution, the electrical power, and the duration of the anodizing process may be selected to form an aluminum oxide coating having predetermined properties, such as for example a predetermined thickness.

The anodized chamber component 300 is removed from the neutral electrolyte solution and rinsed with deionized water. Next, at 204, the anodized chamber component 300 is dipped in a resistive material solution to form a second corrosion resistant coating 310, as depicted in FIG. 3D, atop the aluminum containing body (e.g. directly atop the first corrosion resistant coating 308). In some embodiments, the resistive material solution consists of, or consists essentially of, a resistive material. In some embodiments, the resistive material is yttrium, zirconium, cerium, polytetrafluoroethylene (e.g., Teflon), or the like.

The anodized chamber component 300 is immersed in the resistive material solution and functions as a cathode in the resistive material solution. In some embodiments, the anodized chamber component 300 is coupled to an electrical power source and a current is applied to the anodized chamber component 300. In some embodiments, the anodized chamber component 300 is coupled to the negative terminal of the electrical power source. An anode is immersed in the resistive material solution and is connected to the electrical power source. In some embodiments, the anode is coupled to the positive terminal of the electrical power source. In some embodiments, the electrical power source provided about 20 mV to about 100 volts of power. Process parameters, such as the composition of the resistive material solution, the electrical power, and the duration of the process may be selected to form an resistive material layer having predetermined properties, such as for example a predetermined thickness.

In some embodiments, the chamber component 300 may be annealed in an oxygen containing atmosphere after forming the first corrosion resistant coating 308, or after forming the second corrosion resistant coating 310, or after forming the first corrosion resistant coating 308 and the the second corrosion resistant coating 310. In some embodiments, a suitable oxygen containing gas can be, for example, a gas that provides oxygen and other essentially non-reactive elements, such as ozone (O₃), nitric oxide (NO), nitrous oxide (N₂O), oxygen (O₂), water vapor (H₂O), or combinations thereof. In some embodiments, the chamber component 300 may be annealed at a temperature of about 200 to about 400 degrees Celsius. In some embodiments, the chamber component 300 may be annealed for about 60 to about 1800 seconds. Annealing the chamber component 300 helps to provide a unitary structure between the underlying material and the first corrosion resistant coating and/or the second corrosion resistant coating.

While the foregoing is directed to embodiments of the present disclosure, other and further embodiments of the disclosure may be devised without departing from the basic scope thereof.

1. A method of treating a semiconductor processing chamber component, comprising:
anodizing a semiconductor processing chamber component comprising an aluminum containing body in an anodizing solution comprising a neutral electrolyte and a resistive material to form a corrosion resistant coating atop the aluminum containing body.

2. The method of claim 1, wherein a molar ratio of resistive material to neutral electrolyte in the anodizing solution is about 0.5:1 to about 1:1.

3. The method of claim 1, wherein the neutral electrolyte is ammonium borate (H₁₂BN₃O₃), ammonium adipate, ammonium tartrate, or ammonium phosphate (H₁₂N₃O₄P).

4. The method of claim 1, wherein the resistive material is yttrium, zirconium, cerium, or polytetrafluoroethylene.

5. The method of claim 1, further comprising annealing the semiconductor processing chamber component in an oxygen containing atmosphere after forming the corrosion resistant coating atop the aluminum containing body.

6. The method of claim 1, wherein the corrosion resistant coating has a thickness of about 20 to about 500 nm.

7. A method of treating a semiconductor processing chamber component, comprising:
anodizing a semiconductor processing chamber component comprising an aluminum containing body in a neutral electrolyte solution to form an aluminum oxide layer on a surface of the aluminum containing body; and
contacting the anodized semiconductor processing chamber component with a resistive material solution to form a resistive material layer atop the aluminum oxide layer.

8. The method of claim 7, further comprising applying an electrical power to the semiconductor processing chamber component while dipping the semiconductor processing chamber component in the neutral electrolyte solution.

9. The method of claim 7, further comprising applying electrical power to the semiconductor processing chamber component while dipping the semiconductor processing chamber component in the resistive material solution.

10. The method of claim 7, further comprising annealing the semiconductor processing chamber component in an oxygen containing atmosphere after forming the resistive material layer.

11. The method of claim 7, wherein the neutral electrolyte solution is ammonium borate (H₁₂BN₃O₃), ammonium adipate, ammonium tartrate, or ammonium phosphate (H₁₂N₃O₄P).

12. The method of claim 7, wherein the resistive material solution is yttrium, zirconium, cerium, or polytetrafluoroethylene.

13. A semiconductor processing chamber component, comprising:
an aluminum containing body; and
a corrosion resistant coating covering a surface of the semiconductor processing chamber component wherein the corrosion resistant coating comprises aluminum oxide and a resistive material.

14. The semiconductor processing chamber component of claim 13, wherein the corrosion resistant coating has a thickness of about 20 to about 500 nm.

15. The semiconductor processing chamber component of claim 13, wherein either:
the corrosion resistant coating comprises an integral layer of aluminum oxide and resistive material atop the aluminum containing body; or
the corrosion resistant coating comprises a layer of aluminum oxide atop the aluminum containing body and a layer of resistive material atop the layer of aluminum oxide.

16. The semiconductor processing chamber component of claim 13, wherein the corrosion resistant coating has a thickness of about 20 to about 500 nm.

17. The semiconductor processing chamber component of claim 13, wherein either:
the corrosion resistant coating comprises an integral layer of aluminum oxide and resistive material atop the aluminum containing body; or
the corrosion resistant coating comprises a layer of aluminum oxide atop the aluminum containing body and a layer of resistive material atop the layer of aluminum oxide.

18. The semiconductor processing chamber component of claim 13, wherein the resistive material is yttrium, zirconium, cerium, or polytetrafluoroethylene.

19. The semiconductor processing chamber component of claim 13, wherein the corrosion resistant coating comprises aluminum oxide and a resistive material.

20. The semiconductor processing chamber component of claim 13, wherein the semiconductor processing chamber component comprises a showerhead or a substrate support pedestal.
